(19) United States
(12) Patent Application Publication
(10) Pub. No.: US 2025/0029605 A1
(43) Pub. Date: Jan. 23, 2025

(54) ADAPTIVE AND INTELLIGENT PROMPTING SYSTEM AND CONTROL INTERFACE

(71) Applicant: Boomcloud 360 Inc., Encinitas, CA (US)

(72) Inventor: Zachary Seldess, San Diego, CA (US)

(21) Appl. No.: 18/775,689

(22) Filed: Jul. 17, 2024

Related U.S. Application Data
(60) Provisional application No. 63/514,102, filed on Jul. 17, 2023.

(51) Int. Cl. G10L 15/22; G10L 25/27

(52) U.S. Cl. CPC G10L 15/22; G10L 25/27; G10L 2015/225

(57) ABSTRACT

An adaptive control system may identify, from a user's natural language instructions, an audio parameter of an audio rendering system that the user wishes to adjust. The adaptive control system may identify the context in which the user is providing the instructions, where the context can include sensor information characterizing an environment around the user, device information characterizing the device through which the user is consuming audio, or states of audio parameters as tracked on a parametric space. The adaptive control system may input data characterizing the context into one or more machine learning models to determine a likely audio parameter and a corresponding degree of change the user is requesting through their instruction. The adaptive control system may generate recommended adjustments to audio parameters using machine learning based on the context in which the user is utilizing a controllable system.

### CROSS REFERENCE TO RELATED APPLICATIONS

This application claims the benefit of U.S. Provisional Application No. 63/514,102, filed Jul. 17, 2023, which is incorporated by reference in its entirety.

### TECHNICAL FIELD

The disclosure generally relates to control interfaces, and more specifically to device-informed and context-aware control interfaces.

### BACKGROUND

Audio rendering systems (e.g., speakers or headphones) have fixed controls (e.g., volume). Users are not typically given the option to change controllable parameters that the audio rendering system's control interface does not support. Conventional control interfaces include buttons, sliders, etc. to control audio settings. Users are mostly provided limited controls based on what they generally understand. For example, conventional media players have audio controls with a slider for volume. However, most audio consumers can perceive the effects of other audio controls that conventional systems provide (e.g., low, mid, and high frequency range equalization filters, etc.).

Additionally, each audio rendering system is typically its own isolated environment. A modern audio consumer uses multiple audio rendering systems in one day. The controls on each audio rendering system, on top of being limited and fixed, may not take into account how a user uses another system. For example, a user's portable speaker is not tracking audio adjustments made on a user's car earlier in the day. While a user may have their music preferences (e.g., favorite artist) follow them from device to device, their audio preferences (e.g., bass gain) are isolated per device. In this way, the limited controls of conventional audio rendering systems are not flexible or adaptive.

### SUMMARY

Embodiments relate to an interface for controlling audio using machine learning. An adaptive control system may identify, from a user's input instructions, a controllable parameter of a controllable system. For example, the adaptive control system may identify, from a user's natural language instructions, an audio parameter of an audio rendering system that the user wishes to adjust. The adaptive control system may identify the context in which the user is providing the input instructions, where the context can include sensor information characterizing an environment around the user, device information characterizing the device through which the user is utilizing the controllable system, information specifying characteristics of a signal or stream being rendered, information specifying implied or intended uses-cases for a signal or stream being rendered, or states of controllable parameters as tracked on a parametric space. The adaptive control system can track states of controllable parameters on the parametric space to understand patterns of the user's control (e.g., their preferences) and base predictions of what the user wants to adjust based on the information tracked in the parametric space. The adaptive control system may input data characterizing the context into one or more machine learning models to predict the controllable parameter and a corresponding degree of change the user is requesting through their input instruction.

Additional embodiments relate to an interface provided by the adaptive control system that generates recommended adjustments to controllable parameters using machine learning based on the context in which the user is utilizing a controllable system. For example, the adaptive control system can recommend adjustments to audio parameters using a machine learning model trained on audio parameter adjustments made in various contexts characterized by sensor information, device information, or tracked values of audio parameters on a parametric space.

### BRIEF DESCRIPTION OF DRAWINGS

The disclosed embodiments have other advantages and features which will be more readily apparent from the detailed description, the appended claims, and the accompanying figures (or drawings). A brief introduction of the figures is below.

Figure (FIG. 1 illustrates adjusting a controllable parameter using an adaptive control system, according to an embodiment.

FIG. 2 is a network diagram illustrating a communication environment in which an adaptive control system operates, in accordance with at least one embodiment.

FIG. 3 is a block diagram of a process for processing a user's natural language instruction by the adaptive control system, according to one embodiment.

FIG. 4 illustrates setting a new coordinate in a parametric space, according to an embodiment.

FIG. 5 is a block diagram of a process for training a machine-learned model(s), according to one embodiment.

FIG. 6 depicts an embodiment of audio adjustment performed by the adaptive control system to enhance voice clarity based on the user's environment.

FIG. 7 depicts an embodiment of audio adjustment performed by the adaptive control system to increase volume based on the context in which a user is listening to audio.

FIG. 8 depicts an embodiment of audio adjustment performed by the adaptive control system to strip audio of vocals based on the context in which a user is listening to audio.

FIG. 9 is a flowchart of a process for determining an audio adjustment using a description of an audio parameter, according to an embodiment.

FIG. 10 is a flowchart of a process for determining an audio adjustment using a machine learning model based on a user's natural language instruction, according to an embodiment.

FIG. 11 is a flowchart of a process for recommending an audio adjustment based on a user's audio consumption context, according to an embodiment.

FIG. 12 is a block diagram of a computer, in accordance with at least one embodiment.

### DETAILED DESCRIPTION

The Figures (FIGS.) and the following description relate to preferred embodiments by way of illustration only. It should be noted that from the following discussion, alternative embodiments of the structures and methods disclosed will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated may be employed without departing from the principles described.

### Example System Overview

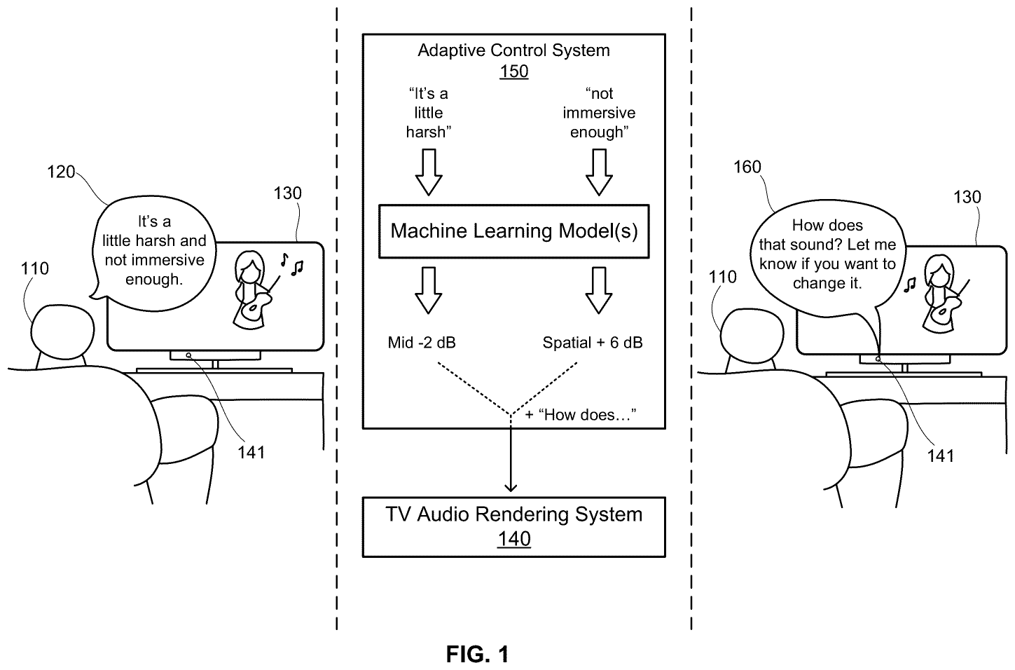

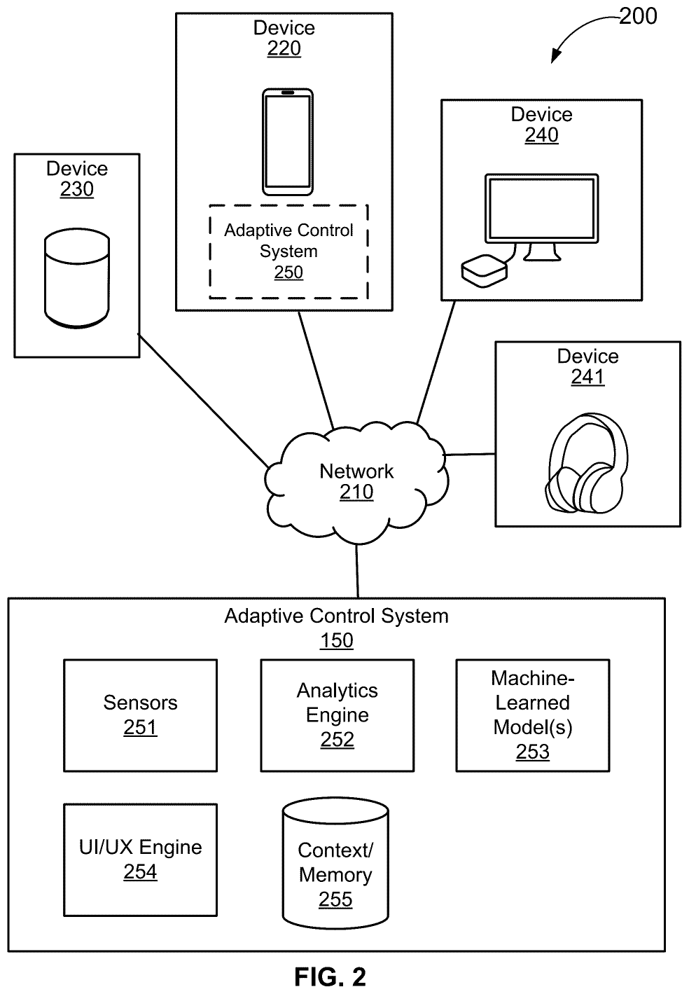

FIG. 1 illustrates adjusting a controllable parameter using an adaptive control system, according to an embodiment. A user 110 consumes audio on their television 130, which includes an audio rendering system 140. The audio rendering system 140 executes audio processing and output as a standalone system (e.g., a television) or supplemental system that couples with another device to output audio (e.g., a portable speaker coupled to a smartphone). An adaptive control system 150 is communicatively coupled with the audio rendering system 140 to enable the user 110 to control audio parameters of the audio rendering system 140. The adaptive control system 150 is further described with respect to FIG. 2. Although the adaptive control system 150 is primarily described with respect to audio controls, the adaptive control system 150 may be applied to user-controllable systems generally. This is also described with respect to FIG. 2.

The user 110 provides a natural language instruction 120 that indirectly references one or more audio parameters of the audio rendering system 140 that they want to adjust. An audio parameter is a controllable characteristic of an audio signal. Examples of audio parameters include spatial processing (e.g., gain adjustments to the side component of a mid/side processor), low-frequency processing (e.g., low-frequency compression ratio or low-frequency makeup gain adjustments to a dynamic range compression system), mid-frequency processing (e.g., gain adjustments to the range between 300 and 5000 Hz of a signal), high-frequency processing (e.g., gain adjustments to the range above 5000 Hz), cross-channel processing, binaural filtering, and voice processing (e.g., voice gain). Examples of audio processing adjustments may be found in U.S. Pat. Nos. 11,432,069 and 11,032,644, which are incorporated by reference. In FIG. 1, the natural language instruction 120 includes “harsh” and “immersive.” The keyword “harsh” describes and indirectly references an audio parameter for mid-frequency processing. The keyword “immersive” describes and indirectly references an audio parameter for spatial processing.

Although natural language inputs are described as inputs to the adaptive control system 150, the adaptive control system 150 may also accept non-verbal gesture as inputs to adjust controllable parameters. For example, a user may provide a swiping gesture or a thumbs up gesture to describe their feedback of an audio parameter's present value, and the adaptive control system 150 may use a sensor (e.g., camera) to capture the user's non-verbal gesture as an input instruction to a machine learning model that identifies an audio parameter represented by the gesture. The adaptive control system 150 may then determine an update to the audio parameter that is likely to improve a user's audio consumption experience. The adaptive control system 150 may use a description of the audio parameter represented by the non-verbal gesture. The non-verbal gesture may be performed in a manner that corresponds to desired update, describing the audio parameter that the user wishes to change. For example, a user can snap louder with a snapping gesture (i.e., the non-verbal gesture) to indicate that they desire a higher adjustment to an audio parameter's value and snap softer to indicate that they desire a lower adjustment.

The adaptive control system 150 identifies the audio parameter that the user 110 wants to adjust based on the natural language instruction 120 and context in which the instruction 120 was made. The natural language instruction 120 has keywords that have a relationship to the audio parameter (e.g., “harsh” relates to “mid-frequency processing” and “immersive” relates to “spatial processing”). The adaptive control system 150 can perform natural language processing to recognize multiple keywords and the likelihood that they refer to audio parameters. For example, if the user 110 is watching a TV show and says “Oof, what he did was a little harsh,” the natural language processing mechanism will likely not flag the keyword of “harsh” as belonging to a user instruction for changing user audio because the use of “harsh” refers to an action by a person rather than to the present audio quality.

The adaptive control system 150 can perform speech recognition to convert user utterance to structured text. The adaptive control system 150 determines that relationship between keywords and audio parameters using machine learning. The adaptive control system 150 includes one or more machine learning models that are trained to identify the audio parameter from one or more keywords in the natural language instruction 120. The machine learning model(s) can be trained on training sets of natural language instructions labeled with audio parameters.

The user's natural language instruction 120 may also indirectly describe an audio parameter. A description of the audio parameter may include an absolute value that the user is requesting (e.g., maximizing the bass or referencing a predefined gain for the bass) or a degree of change that they want to apply to the audio parameter(s). A degree of change includes an amount and direction of change (e.g., increase or decrease). The degree of change may be a normalized adjustment that applies to more than one type of controllable parameter. For example, a degree of change may be +0.5 corresponding to an audio adjustment of +10 decibels (dB) and an image adjustment of +50% sharpness. The keywords “a little harsh” describe the sound being too harsh, which indirectly describes that the user wants to lower the decibel of the mid-frequency processing audio parameter to make the sound less harsh. The keywords “not immersive enough” describe the sound not being immersive enough, which indirectly describes that the user wants to raise the decibel of the spatial processing audio parameter to increase the perceptual presence of immersion within the signal.

The adaptive control system 150 can identify the degree of change that that the user 110 wants to apply to the identified audio parameter(s). The natural language instruction 120 has keywords that have a relationship with a degree of change (e.g., “a little” relates to a small adjustment and “not enough” relates to a medium adjustment). The adaptive control system 150 can determine the relationship between keywords and the degrees of change using machine learning. The machine learning models may be trained to identify the degrees of change from one or more keywords in the natural language instruction 120. A machine learning model can be trained on training sets of natural language instructions labeled with degrees of change. The degree of change may depend on the audio parameter to which the degree of change references (e.g., “a little” in the context of “harsh” may mean to lower the mid-frequency processing decibel while “a little” in the context of “quiet” may mean to increase the volume).

The adaptive control system 150 can determine how to update an audio parameter based on mappings or using a rules-based mechanism. The adaptive control system 150 may map keywords or keyphrases to predefined values of controllable parameters. For example, the adaptive control system 150 may determine that the natural language input “Put me in a movie theater” includes keywords that are mapped to a predefined value of 8 dB for a spatial processing audio parameter. The adaptive control system 150 may use conditional rules to determine how to update an audio parameter. For example, the adaptive control system 150 may determine to update the value of the voice clarity audio parameter to a minimum value (e.g., −20 dB gain) in response to the user providing a natural language input of “Remove the voice” (e.g., the keyword “remove” may be a trigger for this particular rule).

After determining which audio parameters the user 110 is referring to and how to change them, the adaptive control system 150 transmits instructions to the audio rendering system 140 and optionally, includes an additional prompt 160 requesting confirmation from the user that the adjustment is satisfactory. As depicted in FIG. 1, the adaptive control system 150 transmits instructions to the audio rendering system of the TV to lower the mid-frequency processing by −2 dB and increase the spatial processing by 6 dB. The audio rendering system 140 includes a speaker 141 for outputting prompts generated by the adaptive control system 150. The speaker 141 outputs the prompt 160 “How does that sound? Let me know if you want to change it.”

### Adaptive Control System

FIG. 2 is a network diagram illustrating a communication environment 200 in which an adaptive control system 150 operates, in accordance with one embodiment. The communication environment 200 includes a network 210, devices 220, 230, 240, and 241, and the adaptive control system 150. In alternative configurations, different and/or additional components may be included in the communication environment 200. For example, a remote database, although not depicted, may be accessed by the adaptive control system 150 through the network 210 to retrieve rendering system information regarding any of the devices 220, 230, or 240.

Network 210 is communicatively coupled with at least one device (e.g., the device 220, the device 230, and the device 240) and the adaptive control system 150. The network 210 may be one or more networks including the Internet, a cable network, a mobile phone network, a fiberoptic network, or any suitable type of communications network.

Although depicted in FIG. 2 as being separate from the devices 220, 230, and 240 (e.g., located on a remote server that is coupled to devices), the adaptive control system 150 may be incorporated into a device 220, 230, or 240, or any suitable device capable of rendering audio. For example, the device 220 may execute an application with a local adaptive control system 250 that processes user instructions to control audio parameters or generates recommendations to control audio parameters as performed by the adaptive control system 150. Some or all of the components of the adaptive control system such as software modules (e.g., an analytics engine 252) and databases (e.g., a context/memory database 255) may be incorporated into the device.

Devices 220, 230, and 240 are a mobile phone, wireless speaker, and smart television, respectively. Devices may include mobile phones, wireless speakers such as Bluetooth speakers (Bluetooth is a trademark of the Bluetooth Special Interest Group), smart watches, wearable devices, virtual reality or augmented reality devices, smart glasses, wired or wireless headphones, wired or wireless speakers, smart televisions (TV), laptop computers, tablet computers, personal computers, video game consoles, or any suitable electronic device including an audio rendering system for rendering audio content.

Each of the devices 220, 230, and 240 may be associated with an audio rendering system. The audio rendering system may be either located in the device or peripherally connected to the device. For example, a mobile phone has a built-in audio rendering system including speakers. In some embodiments, the audio rendering system may be a peripheral device to another device. For example, a tablet computer may communicate with an audio rendering system including a Bluetooth speaker, such as by using the Bluetooth Advanced Audio Distribution Profile (A2DP) standard to transfer audio signals to the Bluetooth speaker. A device may be coupled to a separate audio rendering system without external network routing equipment to facilitate their connection. For example, the device 220, a mobile phone, may use its built-in Bluetooth communication system to communicate with the device 230, a wireless speaker, without network routing equipment included in the network 210 such as a Wi-Fi router (Wi-Fi is a trademark of the Wi-Fi Alliance). In this example, the device 230 is used as the audio rendering system associated with the device 220, and the native audio rendering system of the device 220 is inactive. In another example, the device 240, a smart TV platform, may support a connection to a device 241 (e.g., support wired or wireless headphones through an analog audio jack, wired USB connection, or Bluetooth). In this example, the device 241 is used as the audio rendering system associated with the device 240, and the native audio rendering system of the device 240 is inactive.

In some embodiments, the audio rendering system associated with a device is characterized by rendering system information. Rendering system information may include various types of data that indicate acoustic properties of the audio rendering system, such as a unique device identifier of the device containing the audio rendering system, a model identifier or product identifier of the device containing the audio rendering system, a position or orientation of the device or audio rendering system relative to a user, a device class of the device containing the audio rendering system, a communication path of an audio signal transmitted to the audio rendering system, an audio codec used by the device, or any suitable combination thereof.

A unique device identifier is an identifier that identifies a particular device. A unique device identifier may include a device serial number, an International Mobile Equipment Identity (IMEI) number, or a Bluetooth address (e.g., for Bluetooth speaker devices).

A model identifier or product identifier defines a particular product. A model identifier or product identifier may be a Stock Keeping Unit (SKU) number, manufacturer ID (MID), or product or model name.

Position or orientation of the device or audio rendering system relative to the user defines how a user has positioned the device (e.g., with integrated speakers) or audio rendering system. For example, a device (e.g., smartphone or tablet) may operate in portrait or landscape mode, depending on how the user is holding the device, and may change which speaker operates as a left speaker and which speaker operates as a right speaker. In another example, the orientation of a mobile phone during a call may indicate which speaker(s) is being used to render audio content.

Device class of the audio rendering system defines a category of the device such as mobile phone, tablet, personal computer, automotive, speaker, headphones, wearable, audiovisual (A/V) receiver, TV, sound bar, or any other suitable category for devices capable of outputting audio.

A communication path of an audio signal defines how audio content is transmitted to the audio rendering system. A communication path may include speakers integrated with the device or speakers of a peripheral device. A communication path may include a route through built-in speakers on a mobile phone or tablet, wireless communication (e.g., wireless streaming) over Bluetooth A2DP, wireless communication over Wi-Fi such as a Wi-Fi-enabled display between mirrored screens, communication over an analog cable connection such as wired headphones connected to a mobile phone, communication over high-definition multimedia interface (HDMI) (HDMI is a trademark of HDMI Licensing Administrator, Inc.), or communication over other cable connection types connected to a mobile phone.

An audio codec defines a program used by the device that encodes or decodes audio content, and this information may indicate the manufacturer or other information about the device.

The adaptive control system 150 includes hardware such as sensors 251. The adaptive control system 150 includes multiple software modules: an analytics engine 252, machine-learned model(s) 253, and a user interface/user experience (UI/UX) engine 254. The adaptive control system 150 further includes a context/memory database 255 that stores sensor information characterizing a user's environment, device information characterizing a user's device, a history of adjustments made to controllable parameters, a history of natural language inputs made by a user, or any suitable information relevant to determine a likely audio adjustment based on a context in which a user is consuming audio.

The sensors 251 monitor a user's environment to determine the context for interpreting instructions for adjusting an audio parameter or to determine a recommendation for the user to adjust an audio parameter. The sensors 251 may include a microphone, camera, location sensors (e.g., Global Positioning System), accelerometers, depth sensors, third party sensors (e.g., sensors on a vehicle that are coupled to the vehicle's entertainment system that serves as an audio rendering system coupled to the adaptive control system 150), or any suitable sensor that characterizes a user's surrounding environment. Although the sensors 251 are shown as being multiple sensors, the adaptive control system 150 may have only one sensor or may have no sensors at all (e.g., the system 150 is communicatively coupled to third-party sensors such a microphone or camera on the device 220).

The analytics engine 252 determines an audio parameter that's being referenced in a natural language input. For example, the natural language instruction 120 of FIG. 1 (“It's a little harsh, but not immersive enough.”) indirectly references two audio parameters: high-frequency processing and spatial processing. The referencing can be indirect (e.g., does not explicitly use the audio parameter in the natural language expression). Examples of audio parameters include spatial processing (e.g., gain adjustments to the side component of a mid/side processor), low-frequency processing (e.g., low-frequency compression ratio or low-frequency makeup gain adjustments to a dynamic range compression system), mid-frequency processing (e.g., gain adjustments to the range between 300 and 5000 Hz of a signal), high-frequency processing (e.g., gain adjustments to the range above 5000 Hz of a signal), cross-channel processing, binaural filtering, and voice processing (e.g., targeted gain adjustments to sung or spoken voice within a signal).

The analytics engine 252 can determine to update a value of an audio parameter based on a description of the audio parameter. The description of the audio parameter may reference or include a degree of change. For example, “Sounds too much like the club,” describes a bass audio parameter as having a higher gain than what the user wants. In this example, the degree of change associated with the audio parameter description may be a negative degree of change to the bass audio parameter. In some embodiments, the analytics engine 252 may determine a degree of change that's being referenced in a natural language input. Degrees of change may be a unitless amount and direction of change within a normalized range between two values (e.g., −1 and 1). For example, the natural language instruction 120 of FIG. 1 indirectly references two different degrees of change: −0.1 and +0.3. A degree of change may correspond to a change having a unit. For example, the degree of change −0.1 corresponds to −2 dB for the high-frequency processing audio parameter and the degree of change of 0.3 corresponds to +6 dB for the spatial processing audio parameter.

A natural language input can reference a degree of change indirectly (e.g., does not explicitly state how many decibels to increase or decrease the audio parameter). Examples of degrees of change are shown in Tables 1 and 2.

TABLE 1
Parameter Increments by Degree of Change (Negative)

| Degrees | −1 | −.9 | −.8 | −.7 | −.6 | −.5 | −.4 | −.3 | −.2 | −.1 | 0 |
|---|---|---|---|---|---|---|---|---|---|---|---|
| Spatial | −20 | −18 | −16 | −14 | −12 | −10 | −8 | −6 | −4 | −2 | 0 |
| Low Ratio | 1:1 | 1:1 | 1:1 | 1:1 | 1:1 | 1:1 | 1:1 | 1:1 | 1:1 | 1:1 | 1:1 |
| Low Gain | −20 | −18 | −16 | −14 | −12 | −10 | −8 | −6 | −4 | −2 | 0 |
| Mid Freq | −20 | −18 | −16 | −14 | −12 | −10 | −8 | −6 | −4 | −2 | 0 |
| High Freq | −20 | −18 | −16 | −14 | −12 | −10 | −8 | −6 | −4 | −2 | 0 |
| Voice | −20 | −18 | −16 | −14 | −12 | −10 | −8 | −6 | −4 | −2 | 0 |

TABLE 2
Parameter Increments by Degree of Change (Positive)

| Degrees | 0 | 0.1 | 0.2 | 0.3 | 0.4 | 0.5 | 0.6 | 0.7 | 0.8 | 0.9 | 1.0 |
|---|---|---|---|---|---|---|---|---|---|---|---|
| Spatial | 0 | 2 | 4 | 6 | 8 | 10 | 12 | 14 | 16 | 18 | 20 |
| Low Ratio | 1:1 | 1:1 | 2:1 | 3:1 | 4:1 | 5:1 | 6:1 | 7:1 | 8:1 | 9:1 | 10:1 |
| Low Gain | 0 | 2 | 4 | 6 | 8 | 10 | 12 | 14 | 16 | 18 | 20 |
| Mid Freq | 0 | 2 | 4 | 6 | 8 | 10 | 12 | 14 | 16 | 18 | 20 |
| High Freq | 0 | 2 | 4 | 6 | 8 | 10 | 12 | 14 | 16 | 18 | 20 |
| Voice | 0 | 2 | 4 | 6 | 8 | 10 | 12 | 14 | 16 | 18 | 20 |

The analytics engine 252 may initiate or reset an audio rendering system's audio parameters to default states. The default states may be the values listed in Tables 1 or 2 under 0 degrees (e.g., low frequency processing compression ratio 1:1 and spatial processing 0 dB). Degrees of changes can be in predefined steps (e.g., Table 1) or interpolated from the predefined steps based on feedback from user. For example, the user provides first feedback stating, “it's too immersive” and after the adaptive control system 150 adjusts the audio, the user provides second feedback stating “now it's not immersive enough.” In this example, the adaptive control system 150 may determine to increase to somewhere between the first and second decibel amounts of spatial processing.

The analytics engine 252 tracks the audio parameters' states and their adjustments in a parametric space. The current or history of parameters' states may be input into the machine-learned model(s) 253 to identify an audio parameter or degree of change from a natural language input or determine a recommended audio adjustment. Furthermore, the analytics engine 252 may track the states of audio parameters across multiple devices. For example, the analytics engine 252 identifies that around a certain time of day, the user has a history of adjusting bass on any device they use to consume audio.

The analytics engine 252 may maintain multiple parametric spaces, where each parametric space may be associated with a different device or environment. For example, the analytics engine 252 may maintain a first parametric space for audio parameters of a first audio rendering system and a second parametric space for audio parameters of a second audio rendering system. The adaptive control system 150 may identify values across one or more parametric spaces as input to a machine-learned model to determine an audio parameter or degree of change in a user's input instruction. For example, multiple parametric spaces representing changes made across different audio rendering systems may show that a low-frequency processing compression ratio was changed from 1:1 to 10:1 across the parametric spaces. The adaptive control system 150 may identify that change in audio parameter, as tracked by the parametric spaces, and use the tracked change as an input into a machine learning model to determine a likelihood that a user's input instructions are referring to the low-frequency processing compression ratio audio parameter and corresponding degree of change.

In some embodiments, the analytics engine 252 may identify, using a parametric space used to track values of audio parameters, a first set of audio adjustments already made on a device. The analytics engine 252 may apply the first set of audio adjustments to a machine learning model to predict a second set of audio adjustments that may not necessarily include all or any of the audio parameters in the first of audio adjustments. For example, the adaptive control system 150 may have previously adjusted voice processing and bass in response to a couple of user input instructions, and the user continues to provide a third input instruction. The analytics engine 252 may determine that the third input instruction, based on the previous adjustments, is referring to a spatial processing adjustment. A machine learning model may be trained on the tracked values of audio parameters on a parametric space over time, and the machine learning model may determine that, based on the audio parameters that the adaptive control system 150 had already adjusted, an audio parameter that is likely to be adjusted next.

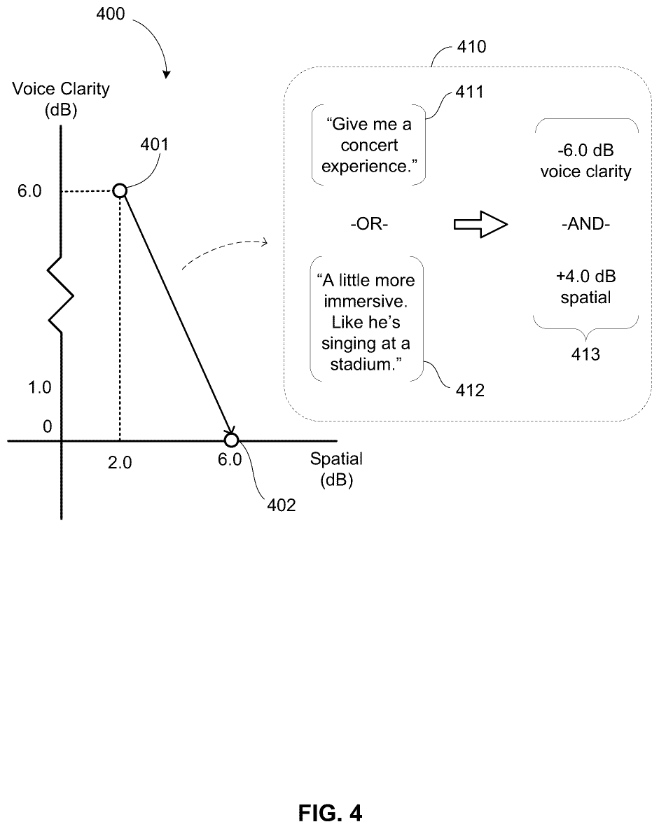

After determining the audio parameter and degree of change based on a user's natural language input, the analytics engine 252 sets a new coordinate for the adjusted audio parameter. For example, if a machine-learned model outputs a 0.3 degree of change and spatial processing as an audio parameter, the analytics engine determines that the audio adjustment should be a +6 dB change for the spatial processing audio parameter. Accordingly, the analytics engine 252 changes the state of the spatial processing audio parameter in the parametric space to be six decibels greater than its current state. One example of setting a new coordinate is shown in FIG. 4.

The analytics engine 252 can customize audio adjustments across devices or user environments. The analytics engine 252 may, in response to determining the user is using a particular device or determining context parameters describing the user's environment, select a particular machine learning model that is tailor-trained for that device or environment. That is, the analytics engine 252 can select a machine learning model based on device information or sensor information describing the context in which the user is consuming audio. For example, the analytics engine 252 receives device information from an audio rendering system describing an application used by the user to consume audio on the audio rendering system. The analytics engine 252 selects, based on the application, one of the machine-learned model(s) 253. For example, the analytics engine 252 selects a machine learning model trained to identify audio parameters in natural language instructions provided during a video streaming application instead of selecting a machine learning model trained to identify audio parameters in natural language instructions provided during a music streaming application.

The analytics engine 252 may also leverage the audio adjustments tracked in the parametric space to determine adjustments in new devices or environments. For example, the parametric space may show that a longer duration of time since the user has attended a concert coincides with greater adjustments for having a more immersive audio experience (e.g., because the user misses the concert experience the longer they have been away from it). In this way, the adaptive control system 150 can understand a user's audio preferences for a given environment or device based on how they've adjusted the audio using the adaptive control system and accordingly, determine future adjustments in different devices or environments.

While the adaptive control system 150 is described primarily in the context of controlling audio, the adaptive control system 150 may be applied to user-controllable systems generally. For example, the adaptive control system 150 may be applied to a smart thermostat, website design, image or video editing, television display settings (contrast, brightness, etc.), or any suitable application where a user controls one or more parameters effecting the outcome of the application.

Different applications of the adaptive control system 150 may have different controllable parameters and degrees of change available. The adaptive control system 150 may identify a controllable parameter or degree of change from a natural language input. For example, the user input of “The website's homepage is too confusing for first time users” may refer to a controllable parameter of number of grid cells, width of whitespace between elements placed in grid cells, presence of primary or secondary navigation, or any suitable webpage design parameter related to an ease of navigation on the website. The adjustment to one such controllable parameter may be fewer number grid cells, greater width of whitespace, etc.

The degrees of change shown in the top rows of Tables 1 and 2 may apply to various applications of the adaptive control system 150, but the corresponding change that depends on the controllable parameter may change. For example, a degree of change of −0.2 for a controllable parameter for the number of grid cells may be −2 grid cells rather than −4 decibels as listed in Table 1 for voice clarity.

Mapping of degrees of change to change of controllable parameters may be linear, as shown in Tables 1 and 2, or non-linear. For example, in Table 1, where spatial processing gain linearly changes from 0 to 20 dB when moving from degree 0.0 to 1.0, spatial processing gain could instead change from 0 to 20 dB along a base-2 logarithmic curve, as shown in Table 3. Mapping of degrees of change to change of controllable parameter may additionally follow more complex patterns, partial patterns, combinations of different patterns, or no pattern at all. For example, spatial gain associated with degrees 0.9 and 1.0 could both be 5 dB, mirroring the gain at degree 0.8 and not conforming to the base-2 logarithmic curve of the other gains associated with degrees 0 through 0.8.

TABLE 3
Parameter Increments by Degree of Change (Positive)

| Degrees | 0 | 0.1 | 0.2 | 0.3 | 0.4 | 0.5 | 0.6 | 0.7 | 0.8 | 0.9 | 1.0 |
|---|---|---|---|---|---|---|---|---|---|---|---|
| Spatial | 0 | 0.039 | 0.078 | 0.156 | 0.313 | 0.625 | 1.25 | 2.5 | 5 | 10 | 20 |

The adaptive control system 150 may map controllable parameter(s) for a given application to a parametric space and track the status of each controllable parameter over time (e.g., as the user adjusts or the system recommends adjustments that the user accepts). The adaptive control system 150 may use machine-learned models to determine controllable parameters or degrees of change from natural language utterances, where the machine-learned models are trained to output the controllable parameters or degrees of change based on input data characterizing the context in which the adjustment is appropriate. That is, the adjustment to the controllable parameter would cause an improved user experience with the application being controlled based on current or previous environments in which the user is using the application.

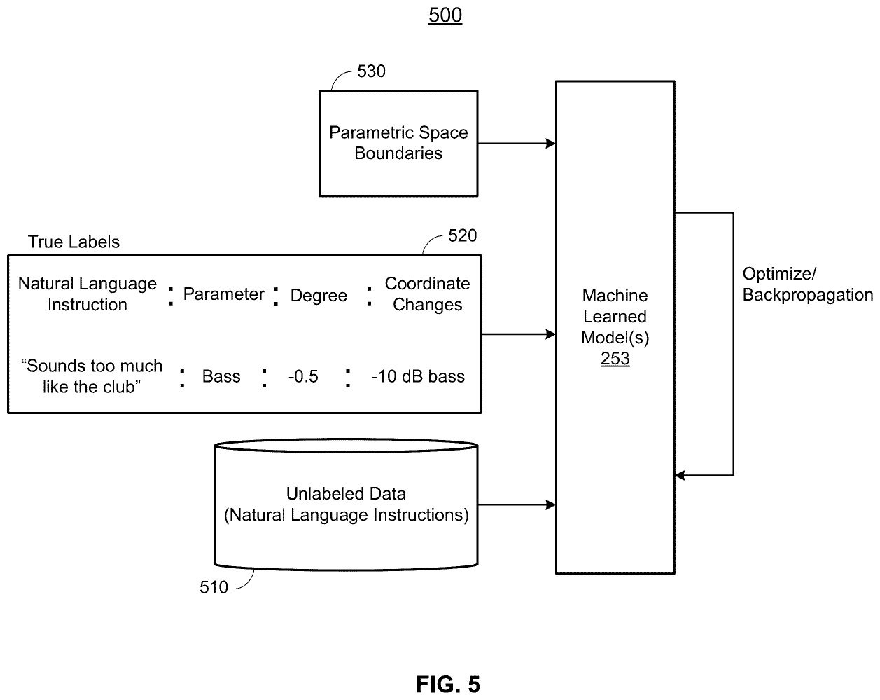

The machine-learned model(s) 253 include one or more models trained to identify an audio parameter of an audio rendering system and a degree of change based on a natural language input and a context in which the user is using the audio rendering system. The machine-learned model(s) 253 may additionally or alternatively include one or more models trained to recommend an audio parameter adjustment based on a context in which the user is using the audio rendering system, where the audio parameter adjustment is a degree of change applied to an audio parameter to adjust the audio parameter's value. Examples of training the machine-learned model(s) 253 are described with respect to FIG. 5.

Example models of the machine-learned model(s) 253 include text classifiers, computer vision models, diagnostic models, transformers, autoencoders, or any suitable trained machine learning model. The adaptive control system 150 may train a model based on one or more training algorithms. Examples of training algorithms may include supervised learning, mini-batch-based stochastic gradient descent (SGD), gradient boosted decision trees (GBDT), support vector machine (SVM), neural networks, logistic regression, naïve Bayes, memory-based learning, random forests, decision trees, bagged trees, boosted trees, or boosted stumps.

In some embodiments, the machine-learned model(s) 253 include a transformer model trained to perform tasks that the adaptive control system 150 receives as requests from client devices or audio rendering systems. The tasks include, but are not limited to, natural language processing (NLP) tasks, audio processing tasks, image processing tasks, video processing tasks, and the like. In one or more embodiments, the machine-learned models deployed by the adaptive control system 150 are models configured to perform one or more NLP tasks. The NLP tasks include, but are not limited to, text generation, query processing, machine translation, chatbots, and the like. In one or more embodiments, the language model is configured as a transformer neural network architecture. Specifically, the transformer model is coupled to receive sequential data tokenized into a sequence of input tokens and generates a sequence of output tokens depending on the task to be performed.

The adaptive control system 150 can receive a request including input data (e.g., text data, audio data, image data, or video data) and encodes the input data into a set of input tokens. The adaptive control system 150 applies a machine-learned model to generate a set of output tokens. Each token in the set of input tokens or the set of output tokens may correspond to a text unit. For example, a token may correspond to a word, a punctuation symbol, a space, a phrase, a paragraph, and the like.

When the machine-learned model is a language model, the sequence of input tokens or output tokens are arranged as a tensor with one or more dimensions, for example, one dimension, two dimensions, or three dimensions. For example, one dimension of the tensor may represent the number of tokens (e.g., length of a sentence), one dimension of the tensor may represent a sample number in a batch of input data that is processed together, and one dimension of the tensor may represent a space in an embedding space. However, it is appreciated that in other embodiments, the input data or the output data may be configured as any number of appropriate dimensions depending on whether the data is in the form of image data, video data, audio data, and the like. For example, for three-dimensional image data, the input data may be a series of pixel values arranged along a first dimension and a second dimension, and further arranged along a third dimension corresponding to RGB channels of the pixels.

In one or more embodiments, the language models are large language models (LLMs) that are trained on a large corpus of training data to generate outputs for the NLP tasks. An LLM may be trained on massive amounts of text data, often involving billions of words or text units. The large amount of training data from various data sources allows the LLM to generate outputs for many tasks. In one instance, the LLM may be trained and deployed or hosted on a cloud infrastructure service. The LLM may be pre-trained by the adaptive control system 150 or one or more entities different from the adaptive control system 150. An LLM may be trained on a large amount of data from various data sources. For example, the data sources include websites, articles, posts on the web, and the like. From this massive amount of data coupled with the computing power of LLM's, the LLM is able to perform various tasks and synthesize and formulate output responses based on information extracted from the training data.

While a LLM with a transformer-based architecture is described as a primary embodiment, it is appreciated that in other embodiments, the language model can be configured as any other appropriate architecture including, but not limited to, long short-term memory (LSTM) networks, Markov networks, BART, generative-adversarial networks (GAN), diffusion models (e.g., Diffusion-LM), and the like.

The UI/UX engine 254 can generate and transmit instructions to an audio rendering system. The UI/UX engine 254 may also receive a natural language instruction from a user to make an adjustment to an audio parameter of an audio rendering system. The UI/UX engine 254 can include a conversational agent to output a notification to the user describing the audio adjustment being made in a natural language expression. For example, the UI/UX engine 254 determines that an adjustment of −2 dB gain to the high-frequency processing may be expressed in natural language as “We've lowered the brightness of the audio.” The UI/UX engine 254 may use an application programming interface (API) to receive and transmit data and instructions between an audio rendering system or client device used to interface with a client adaptive control system application.

The context/memory database 255 stores data used by the adaptive control system 150 to fulfill or recommend audio adjustments. The context/memory database 255 stores a parametric embedding space on which the states of audio parameters of an audio rendering system are tracked. In this way, the context/memory database 255 stores changes in the audio parameters over time. The context/memory database 255 can store a history of a user's natural language inputs used by the adaptive control system 150 to adjust audio parameters. For example, the context/memory database 255 can store previous natural language instructions that the user provided to deliberately control an audio parameter. In another example, the context/memory database 255 can store a natural language statement that the user did not necessarily express to control an audio parameter, but the adaptive control system 150 determined a recommendation from the statement to adjust an audio parameter.

The context/memory database 255 may store previous natural language inputs to enable the adaptive control system 150 to understand short-term context across natural language inputs provided over time. For example, the adaptive control system 150 may understand a first input of “the audio is a little too enveloping” and a second input two minutes later of “it's not immersive enough” to both be referring to the audio and in particular, to a spatial processing audio parameter.

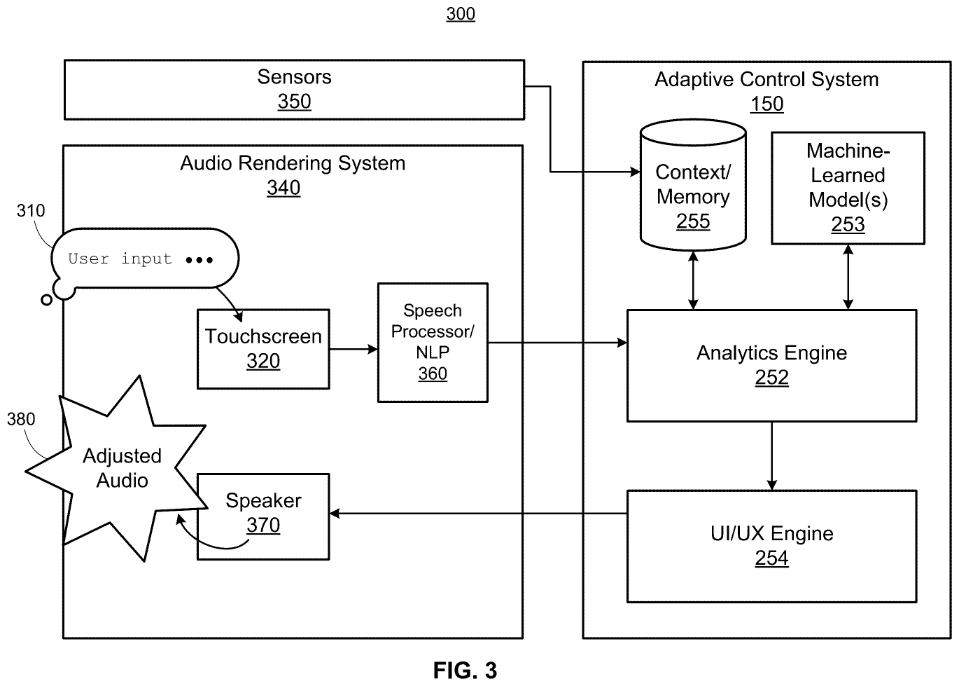

FIG. 3 is a block diagram 300 of a process for processing a user's natural language instruction by the adaptive control system 150, according to one embodiment. In particular, the adaptive control system 150 processes the user's natural language instruction to produce an audio change at an audio rendering system.

The user input may be provided in a text form. In a first example, a user uses touchscreen 320 of the audio rendering system or although not depicted, of an external touchscreen coupled to the audio rendering system (e.g., the user uses the touchscreen of their phone to provide the user input, and the phone is connected to an in-vehicle entertainment system's speakers). In another example, a user types “Move vocals into the background” into the touchscreen 320.

The audio rendering system 340 may process the user input 310 using a speech processor or natural language processor 360, which may determine the meaning of one or more words in the user input 310. In response to determining that at least one word of the user input 310 refers to an instruction for adjusting audio, the speech processor/NLP 360 provides the user input 310 to the analytics engine 252 of the adaptive control system 150.

The analytics engine 252 identifies an audio parameter or degree of change referenced in the user input 310. The analytics engine 252 uses information within the context/memory database 255 and the machine-learned model(s) 253 to identify the audio parameter or degree of change.

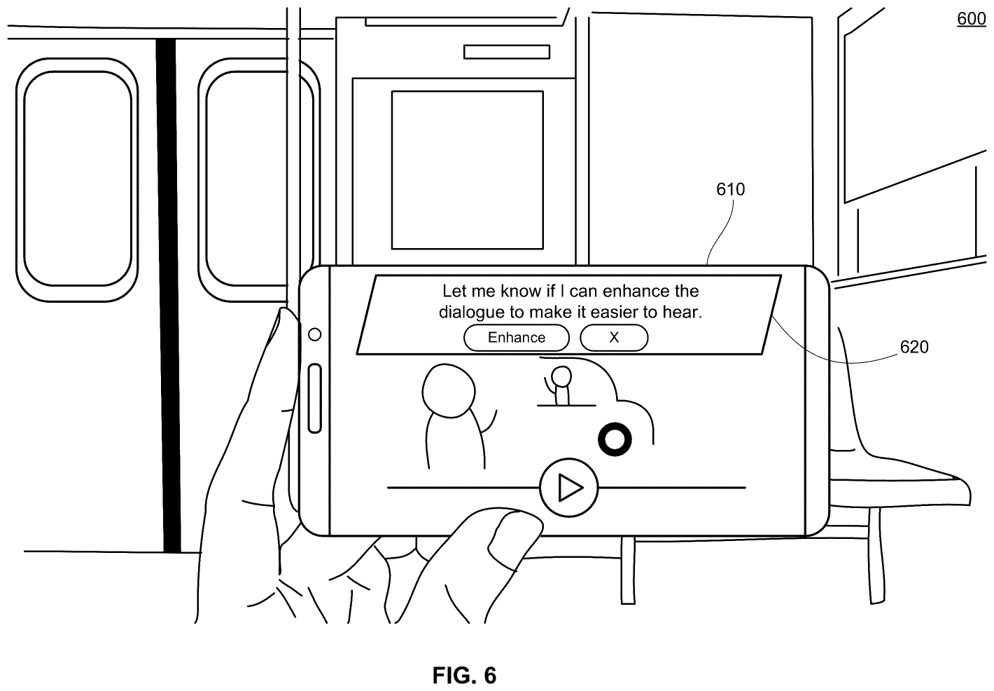

The context/memory database 255 receives information from the sensors 350. The sensors 350 are any suitable tool for monitoring the context in which a user would consume audio. Sensors can include location sensors, accelerometers, cameras, microphones, or biometric sensors. Although not depicted, the context/memory database 255 can also receive device information from the audio rendering system or devices coupled to the audio rendering system. Device information includes rendering system information (e.g., a model identifier or product identifier of the device containing the audio rendering system). Device information may also include how the user has used the device (e.g., the user's usage of calendar applications, media applications, fitness applications, or any suitable software application that provides context for a user's audio consumption). Additional examples of sensor information or device information are described with respect to FIG. 6-8. In applications of the adaptive control system 150 that enable a user to additionally or alternatively control non-audio parameters, the context/memory database 255 may receive information from sensors that monitor contexts in which a user would use a controllable system (e.g., web design tool, image editing tool, etc.). The context/memory database 255 can receive device information from devices coupled to the controllable system (e.g., a smartphone coupled to the web design tool or a camera coupled to an image editing tool).

The analytics engine 252 may input the user input 310 or information from the context/memory database 255 into to the machine-learned model(s) 253. The analytics engine 252 may create a vector representing the user input 310 and information from the context/memory database 255. The analytics engine 252 may input the vector into the machine-learned model(s) 253, which may be trained to output an audio parameter or degree of change based on the vector input.

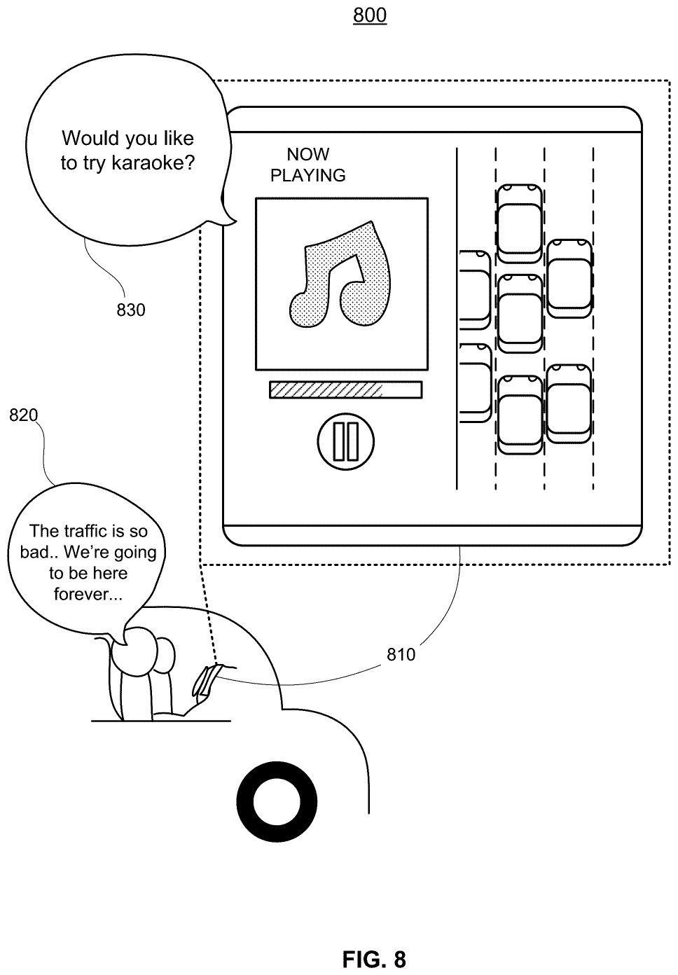

The machine-learned model(s) 253 may be trained using a dataset of unlabeled user inputs and labeled user inputs (e.g., labeled with audio parameter or degree of change). The training process is further described with respect to FIG. 8.

If the analytics engine 252 determines that there is no audio parameter mentioned in the user input yet identifies a degree of change in the user input, the analytics engine 252 may refer back to a previously provided user input (e.g., the previously provided user inputs stored in the context/memory database 255) to determine an audio parameter from a previously provided user input to which the degree of change most likely refers

If the analytics engine 252 determines that there is no degree of change mentioned in the user input yet identifies an audio parameter in the user input, the analytics engine 252 may apply a default degree of change and prompt the user for feedback to adjust the degree of change as needed. Alternatively, the analytics engine 252 may determine a degree of change that the user most likely desires based off context or previously requested degrees of change.

For example, the analytics engine 252 identifies context such as the device that the user is currently using as their audio rendering system and a previously requested degree of change that the user has requested multiple times when using that particular device, and using one of the machine-learned model(s) 253 or other statistical predictive algorithm, determines that the likely desired degree of change is that previously requested degree of change

The analytics engine 252 determines the audio parameter adjustment based on the audio parameter or degree of change output by the machine-learned model(s) 253. The analytics engine 252 provides the determined audio parameter adjustment to the UI/UX engine 254.

The UI/UX engine 254 formats the audio parameter adjustment into an instruction that is understandable by the audio rendering system 340. For example, the UI/UX engine 254 uses an API associated with the audio rendering system 340. The UI/UX engine may include a conservational agent that outputs a prompt to the user. The prompt may notify the user of the audio parameter being adjusted or prompt the user for feedback of the adjustment (e.g., where the feedback can be used by the adaptive control system 150 to iteratively adjust the audio parameter until the user's desired adjustment is achieved).

The audio rendering system 340 may output the adjusted audio 380 via the speaker 370, where the audio rendering system 340 renders the adjusted audio 380 based on the instructions provided by the adaptive control system 150.

FIG. 4 illustrates setting a new coordinate in a parametric space 400, according to an embodiment. For the sake of clarity, the parametric space 400 is depicted as being defined by two audio parameters, voice clarity and spatial processing. However, the adaptive control system 150 may track a parametric space of one or more controllable parameters (e.g., audio parameters).

The parametric space 400 tracks the states of one or more audio parameters associated with an audio rendering system. A first coordinate 401 reflects an initial state of the voice clarity audio parameter at 6 dB and an initial state of the spatial processing audio parameter at 2 dB. A second coordinate 402 reflects an updated state of the voice clarity audio parameter at 0 dB and an updated state of the spatial processing audio parameter at 6 dB.

The change from the first coordinate 401 to the second coordinate 402 reflects processing 410 by the adaptive control system 150. The adjustments 413 are the result of the adaptive control system 150 processing a first natural language input 411 or a second natural language input 412. The first natural language input 411, “Give me a concert experience,” indirectly references one or more audio parameters. The machine-learned model(s) 253 are trained to identify these audio parameters. For example, a machine-learned model may be trained to strongly associate audio parameters of spatial processing and voice clarity with the term “concert.”

The second natural language input 412, “A little more immersive. Like he's singing at a stadium,” also indirectly references one or more audio parameters. Similarly, the machine-learned model(s) 253 are trained to identify these audio parameters. For example, a machine-learned model may be trained to strongly associate the audio parameter of spatial processing with the keywords “immersive” or “stadium” and associate the audio parameter of voice clarity with the keyword “stadium.”

FIG. 5 is a block diagram 500 of a process for training the machine-learned model(s) 253, according to one embodiment. The example training process of FIG. 5 shows a supervised training process, but the machine-learned model(s) 253 may be trained using any suitable training process not limited to supervised training. The block diagram 500 includes unlabeled data 510, true labels 520, and parametric space boundaries 530 to train the machine-learned model(s) 253. The training process may be performed by the adaptive control system 150.

The unlabeled data 510 includes natural language instructions (e.g., user utterances or text). The true labels 520 include mappings of natural language instructions, controllable parameters, degrees, and coordinate changes on a parametric space. One example true label maps the natural language instruction “sounds too much like the club” with audio parameter “bass,” degree of change “−0.5,” and coordinate change on the parametric space of “−10 dB” bass.

In some embodiments, the true labels may omit a coordinate change and the machine-learned model(s) 253 may still be trained to output a degree from which the adaptive control system 150 can determine a corresponding coordinate change (e.g., from a lookup table like Tables 1 or 2 or from interpolating degree-coordinate change mappings).

Although the true labels 520 refer to controlling audio parameters, the true labels 520 may include mappings of any natural language instruction that references a controllable parameter or degree of change for adjusting the controllable parameter. For example, the true labels 520 may include a mapping of “It's really dry,” which a user of an automated oven expresses to describe a cake baked by the oven, to a parameter of “temperature” and degree of “−2” (which can correspond to a degree change of −20 degrees fahrenheit) to control the oven.

The parametric space boundaries 530 include limits on the parametric coordinate space to which the adjustments to the controllable parameters are limited. For example, the parametric space boundaries 530 can include limits for audio parameters on the parametric coordinate space 400 specifying that voice clarity is bounded by values of −20 to 20 decibels and that spatial processing is bounded by values of −20 to 20 decibels. The adaptive control system 150 uses the parametric space boundaries 530 to train the machine-learned model(s) 253 to avoid exceeding specified boundaries. In this way, the adjustments to controllable parameters output by the machine-learned model(s) 253 may be designed not to exceed the boundaries defined by the parametric space boundaries 530. The adaptive control system 150 uses the true labels 520 to train the machine-learned model(s) 253 to label the unlabeled data 510. The adaptive control system 150 can optimize the machine-learned model(s) 253 predictions for how to label the unlabeled data 510 via back propagation.

The adaptive control system 150 can train different models of the machine-learned model(s) 253 with different training data sets. The adaptive control system 150 can train a first model to be customized to make audio parameter or degree of change determinations for a first environment and train a second model to be customized for a second environment. For example, the adaptive control system 150 can use a first set of true labels to train the first model, where the first set of true labels are associated with the first environment, and use a second set of true labels to train the first model, where the second set of true labels are associated with the second environment. The adaptive control system 150 can similarly train different models to make determinations that are customized for different devices. For example, the adaptive control system 150 trains a first model using true labels associated with a first audio rendering system and trains a second model using true labels associated with a second audio rendering system. The same natural language instruction may be mapped to different audio parameters or degrees depending on the environment or audio rendering system.

Although not shown, the adaptive control system 150 can train one or more of the machine-learned model(s) 253 to determine a recommended audio parameter or degree of change based on an input characterizing a user's environment in which they are consuming audio (i.e., the user's context).

The adaptive control system 150 can generate a training dataset including audio parameters or associated degrees of change that are labeled with one or more context parameters. Context parameters describe the context in which a user is consuming audio and may include sensor or device information. The adaptive control system 150 can train the one or more of the machine-learned model(s) 253 with the labeled data and unlabeled context parameters. The adaptive control system 150 may also use parametric space boundaries 530 to train the models so that recommended degrees of change output by the models do not exceed the parametric space boundaries 530. The adaptive control system 150 may use the tracked states of one or more audio parameters on a parametric space as one of the context parameters for input to the machine learning model. For example, the adaptive control system 150 may recommend increasing voice processing based on a tracked history of values of a volume audio parameter being increased over time. A corresponding natural language prompt that includes the recommendation may state, “Is the audio still hard to hear despite increasing the volume? Would you like to try adjusting the dialogue audio so that it's more intelligible?” In response to receiving a user response accepting the recommendation, the adaptive control system 150 may adjust the voice clarity audio parameter by a positive decibel.

After using the trained machine-learned model(s) 253 to identify audio parameters or degrees of change from a natural language instruction, the adaptive control system 150 may prompt the user for feedback on the audio adjustment and retrain the machine-learned model(s) 253 using feedback received from the user. Similarly, after using the trained machine-learned model(s) 253 to recommend an audio parameter or degrees of change based on a user's context, the adaptive control system 150 may prompt the user for feedback on the recommendation and retrain the machine-learned model(s) 253 using the feedback received from the user.

### Example Applications and Applications of the Adaptive Control System

FIG. 6 depicts an embodiment 600 of audio adjustment performed by the adaptive control system 150 to enhance voice clarity based on the user's environment. A user is riding on public transit where the background audio is very noisy. The user is consuming audio from their smartphone. Specifically, the user is consuming audio with dialogue (e.g., a TV show, movie, documentary, interview, etc.).

The adaptive control system 150 can monitor the user's environment and automatically determine a recommended audio adjustment and prompt the user to implement this adjustment. The adaptive control system 150 receives sensor information from the user device 610 or the audio rendering system coupled to the user device 610 (e.g., headphones coupled to the user device 610). Sensor information can include GPS location or a change of GPS location over time to determine that the user is likely traveling, audio information from a microphone (e.g., decibel levels or a frequency response of the surrounding environment) to determine that the user is in a loud environment.

The adaptive control system 150 can receive device information that includes information about the audio rendering system or the audio communication path (e.g., the user device 610 or a pair of headphones coupled to the user device 610 that are presently outputting the audio). For example, the device information reflects how the audio is being output from the headphones and specification data of the headphones (e.g., sensitivity, frequency response, maximum input power, etc.). Device information can also include information on how the user is using the device. For example, device information can include calendar information from a calendar application to determine that the user is likely traveling.

The adaptive control system 150 inputs the sensor information and device information of the current environment or prior environments (e.g., the prior “current environment” information that was stored into the context/memory database 255) into one or more of the machine-learned model(s) 253, where the one or more machine learning models are trained to receive contextual information of the user's environment and output one or more likely audio parameters paired with degrees of change that will likely improve the audio quality for the user in the current environment. The adaptive control system 150 may input the device information (audio communication path, specification data of the headphones, the application the user is presently using, etc.) or sensor information (GPS data, audio information of the user's surroundings, etc.) into a machine-learned model.

The adaptive control system 150 may apply a first machine-learned model to classify the device information or sensor information. For example, the adaptive control system 150 may apply a first machine-learned model to classify an action that the user is likely doing (e.g., commuting based on their GPS data, calendar information, and the audio information of their surroundings). The adaptive control system 150 may then apply a second machine learned model to determine a recommended audio parameter and degree of change based on the audio communication path and the output of the first machine-learned model.

The machine-learned model(s) 253 may output a recommended audio parameter of voice clarity and a positive adjustment (e.g., 0.2 degrees or +4 dB) in response to input information describing the user's current environment of watching a movie using their headphones on a noisy subway. The UI/UX engine 254 may cause a prompt 620 to be displayed on the user device 610. The prompt may include one or more interactable elements for the user to accept or reject the recommendation.

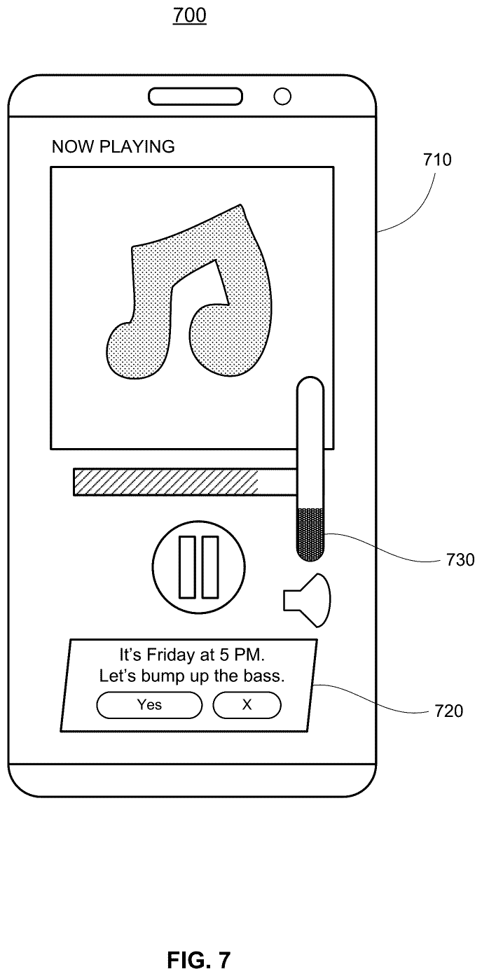

FIG. 7 depicts an embodiment 700 of audio adjustment performed by the adaptive control system 150 to increase volume based on the context in which a user is listening to audio. A user is listening to music on their user device 710 (e.g., a smartphone) on a Friday, and the time of day reaches a time commonly associated with clocking out of work. The adaptive control system 150 can use the machine-learned model(s) 253 to automatically recommend that the user increase their bass.

The adaptive control system 150 may periodically query the user device 710 for sensor information or device information such as the application(s) presently used (e.g., a music application), the user's calendar application information (e.g., their calendar showing when they clock out of work), and the present time and day for the user. The adaptive control system 150 inputs the sensor information and device information into the machine-learned model(s) 253, which is trained to output an audio parameter and degree of change that is likely to improve the audio quality or user experience in consuming audio given the user's current environment or context.

The machine-learned model(s) 253 may output an audio parameter of bass and a degree of change of 0.2 degrees (+0.4 dB) given the input that the user is using a music application and is likely clocking out of work on a Friday. The UI/UX engine 254 causes a prompt 720 and a visual indicator 730 of the audio parameter to be displayed on the user device 710. The UI/UX engine 254 may determine a natural language dialogue to express the audio parameter and degree of change output by the machine-learned model(s) 253. For example, a conversational agent of the UI/UX engine 254 uses a large language model to generate the recommendation dialogue that includes “bass,” language reflecting the +4 dB change, and a reasoning for the recommendation. The prompt 720 recommends that the user increase their bass because of the time and day of week.

FIG. 8 depicts an embodiment 800 of audio adjustment performed by the adaptive control system 150 to strip audio of vocals based on the context in which a user is listening to audio. Users are listening to music using their audio rendering system 810, which may coincide or be integrated with an in-vehicle entertainment system. The users are stuck in bumper-to-bumper traffic, as monitored by sensors of the vehicle (e.g., lidar sensors, cameras, etc.). One of the users provides, through a microphone sensor, a user input 820 of “The traffic is so bad. We're going to be here forever.” In one example of providing this input 820, the audio rendering system 810 may include a client application having the functions of the adaptive control system 150, where a user can choose when to provide a natural language input that the adaptive control system 150 parses. Alternatively, the audio rendering system 810 or adaptive control system 150 may monitor continuously monitor the user's audio for the occurrence of an activation word that causes them to parse an utterance following the activation word.

The adaptive control system 150 inputs sensor information characterizing the context in which the user consumes audio into the machine-learned model(s) 253. From the vehicle sensor data and microphone sensor data, the machine-learned model(s) 253 may output a recommended audio parameter or degree of change to an audio parameter. For example, the machine-learned model(s) may output an audio parameter of voice clarity and degree of change of −1.0. This adjustment to decrease voice clarity may simulate an instrumental version of the audio and enable one or more of the users to try karaoke in their vehicle as they are stuck in traffic. The adaptive control system 150 may generate a prompt for an LLM model, which may be one of the machine-learned model(s) 253, requesting dialogue to phrase the determined audio parameter or degree of change to the users. The LLM model may output the dialogue 830 stating “Would you like to try karaoke?” to express the recommended audio adjustment of −20 dB to the voice clarity audio parameter. The UI/UX engine 254 may transmit the dialogue 830 output by the LLM model to the audio rendering system 810 for the speaker of the vehicle to present to the users for their response. The adaptive control system 150 may use the user's acceptance or rejection of the dialogue 830 to re-train the machine-learned model(s) 253 used to generate the recommendation.

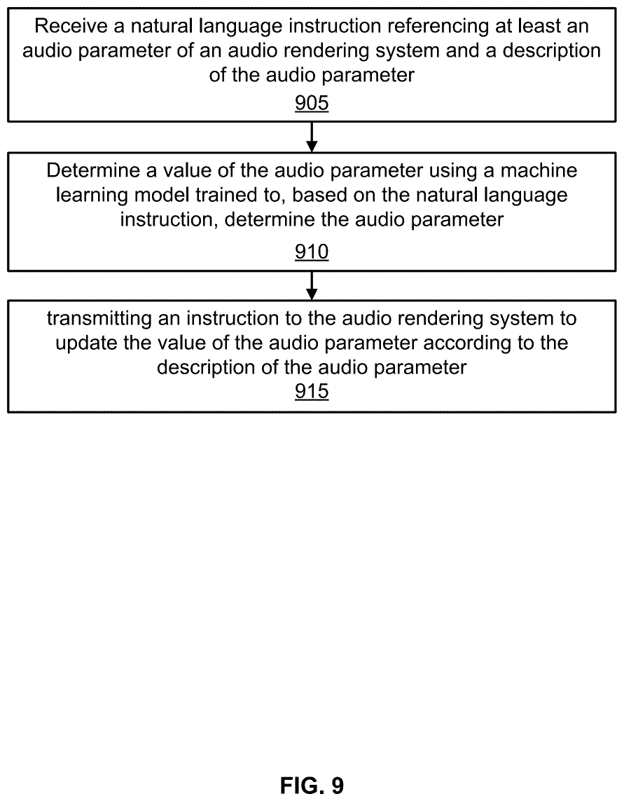

FIG. 9 is a flowchart of a process 900 for determining an audio adjustment using a description of an audio parameter, according to an embodiment. In some embodiments, the adaptive control system 150 performs steps of the process 900 in parallel, in different orders, or performs different steps. For example, although not shown, the adaptive control system 150 may receive device information from the audio rendering system, where the device information includes an application that is presently used by a user to consume audio on the audio rendering system. The adaptive control system 150 may then select, based on that application, the machine learning model used in the process 900 from multiple machine learning models (e.g., different models trained on device information from respective audio rendering systems).

The adaptive control system 150 receives 905 a natural language instruction referencing at least an audio parameter of an audio rendering system and a description of the audio parameter. In a first example, the adaptive control system 150 receives 905 a user instruction stating “Give me a concert experience.” This natural language instruction indirectly references an audio parameter of spatial processing and describes the audio parameter indirectly (i.e., how the spatial processing gain would emulate a concert experience). This indirect description may further reference or include a degree of change that the user is targeting for the audio parameter (e.g., to increase the spatial processing gain to a certain value to achieve more of a concert experience).

In a second example, the adaptive control system 150 receives 905 a user instruction stating “Remove the voice.” This natural language instruction references an audio parameter of voice clarity and describes the audio parameter indirectly (e.g., the audio parameter is currently at a value large enough that the user can still hear vocals in the audio).

The adaptive control system 150 determines 910 a value of the audio parameter using a machine learning model trained to, based on the natural language instruction, determine the audio parameter. In the first example, the adaptive control system 150 determines, using the machine learning model, that the natural language instruction is referring to at least an audio parameter of spatial processing. The adaptive control system 150 may also determine, using the machine learning model, that the natural language instruction is referring to another audio parameter such as voice clarity (i.e., a concert experience may be both surround sound but also have a diminished voice clarity due to the echo of a stadium). The adaptive control system 150 determines 905 a value of the spatial processing audio parameter is presently at 0 dB gain. The adaptive control system 150 may also determine that a value of the voice clarity audio parameter is currently at 2 dB gain.

In the second example, the adaptive control system 150 determines, using the machine learning model, that the natural language instruction is referring to an audio parameter of voice clarity. The adaptive control system 150 determines 905 a value of the voice clarity audio parameter is currently at 0 dB.

The adaptive control system 150 transmits 915 an instruction to the audio rendering system to update the value of the audio parameter according to the description of the audio parameter. The adaptive control system 150 can determine the instruction using the description of the audio parameter prior to transmitting 915 the instruction. In the first example, the adaptive control system 150 can determine that “a concert experience” are words mapped to a predefined value of the spatial processing audio parameter (e.g., 6 dB). The adaptive control system 150 may also determine another mapping of “a concert experience” to a predefined value of the voice clarity audio parameter (e.g., −4 dB). These predefined values may be a predefined coordinate on the parametric space where the values of audio parameters can be tracked by the adaptive control system 150. In the first example, the adaptive control system 150 transmits 915 an instruction to at least change the current value of the spatial processing audio parameter at the audio rendering system from a gain of 0 dB to 6 dB. The instruction may also cause the audio rendering system to change the voice clarity audio parameter from a gain of 2 dB to −4 dB.

In the second example, the adaptive control system 150 can determine that “remove” maps to a minimum value of the voice clarity audio parameter on a parametric space (e.g., −20 dB). The adaptive control system 150 may then transmit 915 an instruction to change the gain of the voice clarity audio parameter to −20 dB at the audio rendering system.

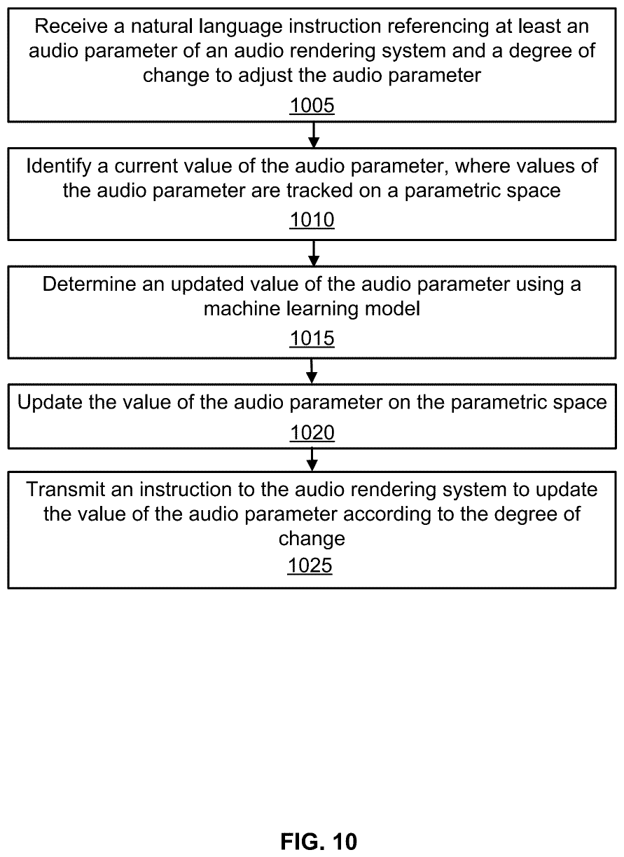

FIG. 10 is a flowchart of a process 1000 for determining an audio adjustment using a machine learning model based on a user's natural language instruction, according to an embodiment. In some embodiments, the adaptive control system 150 performs steps of the process 1000 in parallel, in different orders, or performs different steps. For example, although not shown, the adaptive control system 150 may generate a natural language prompt requesting feedback from the user regarding the updated value of the audio parameter and re-train a machine learning model based on the feedback.

The adaptive control system 150 receives 1005 a natural language instruction referencing at least an audio parameter of an audio rendering system and a degree of change to adjust the audio parameter. The natural language instruction can reference the audio parameter indirectly using one or more descriptive keywords. For example, “immersive” may be a descriptive keyword describing a spatial processing audio parameter. The natural language instruction can be a user utterance or a textual message.

The adaptive control system 150 identifies 1010 a current value of the audio parameter, where values of the audio parameter may be tracked on a parametric space. Although the process 1000 references one audio parameter and one degree of change, the adaptive control system 150 can identify two or more audio parameters and associated degrees of change to those audio parameters within the natural language instruction.

The adaptive control system 150 determines 1015 an updated value of the audio parameter using a machine learning model. The machine learning model may be trained to, based on the natural language instruction and the tracked values of the audio parameter on the parametric space, determine the audio parameter and the degree of change. The tracked values of the audio parameter can include a change in the values of the audio parameter over instructions transmitted to the audio rendering system. That is, the adaptive control system 150 updates the value of the audio parameter on the parametric space at each instruction transmitted to the audio rendering system, and those updated values are included in the tracked values of the audio parameter used as input to the machine learning model. The adaptive control system 150 can additionally receive device information from the audio rendering system. The machine learning model may be further trained to determine the audio parameter and the degree of change based on the device information.

The adaptive control system 150 updates 1020 the value of the audio parameter on the parametric space. FIG. 4 shows one example of updating values of audio parameters on the parametric space 400. The adaptive control system 150 transmits 1025 an instruction to the audio rendering system to update the value of the audio parameter according to the degree of change. For example, although not depicted in FIG. 1, the audio rendering system 140 may change the mid-frequency gain by −2 dB and spatial processing side gain by +6 dB according to the instruction provided by the adaptive control system 150.

The adaptive control system 150 can update 1020 the value of the audio parameter from a default state on the parametric space. For example, the adaptive control system 150 can update a low-frequency processing compression ratio from a default state of 1:1 by +0.1 degrees, causing its updated state to be 1:1 (as shown on Table 2). The adaptive control system 150 may further update the low-frequency processing compression ratio from the first updated state of 1:1 by +0.2 degrees to be a second updated state of 3:1 (as shown on Table 2).

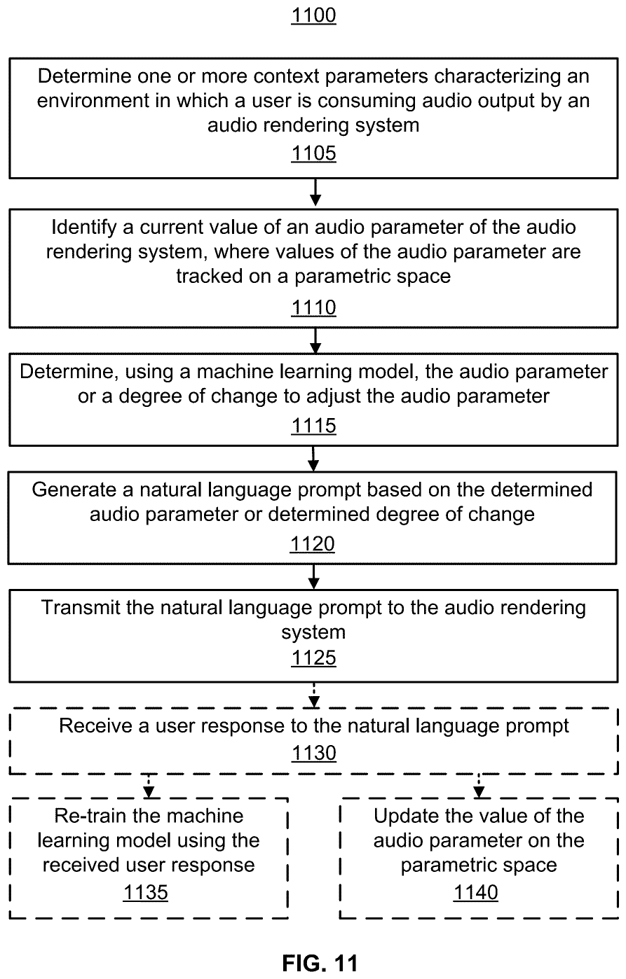

FIG. 11 is a flowchart of a process 1100 for recommending an audio adjustment based on a user's audio consumption context, according to an embodiment. In some embodiments, the adaptive control system 150 performs steps of the process 1100 in parallel, in different orders, or performs different steps. For example, although not shown, the adaptive control system 150 may classify sensor information using a machine learning model to determine the one or more context parameters. The process 1100 is relevant to the embodiments shown in FIGS. 6-8 where the adaptive control system 150 uses information about the user's device(s) or environment to recommend an audio adjustment.

The adaptive control system 150 determines 1105 one or more context parameters characterizing an environment in which a user is consuming audio output by an audio rendering system. The adaptive control system 150 identifies 1110 a current value of an audio parameter of the audio rendering system, where values of the audio parameter are tracked on a parametric space. The adaptive control system 150 determines 1115, using a machine learning model, the audio parameter or a degree of change to adjust the audio parameter.

The adaptive control system 150 generates 1120 a natural language prompt based on the determined audio parameter or determined degree of change. The adaptive control system 150 transmits 1125 the natural language prompt to the audio rendering system. Optionally, the adaptive control system 150 receives 1130 a user response to the natural language input. The adaptive control system 150 may also optionally re-train 1135 the machine learning model using the received user response and update 1140 the value of the audio parameter on the parametric space.

### Example Computer

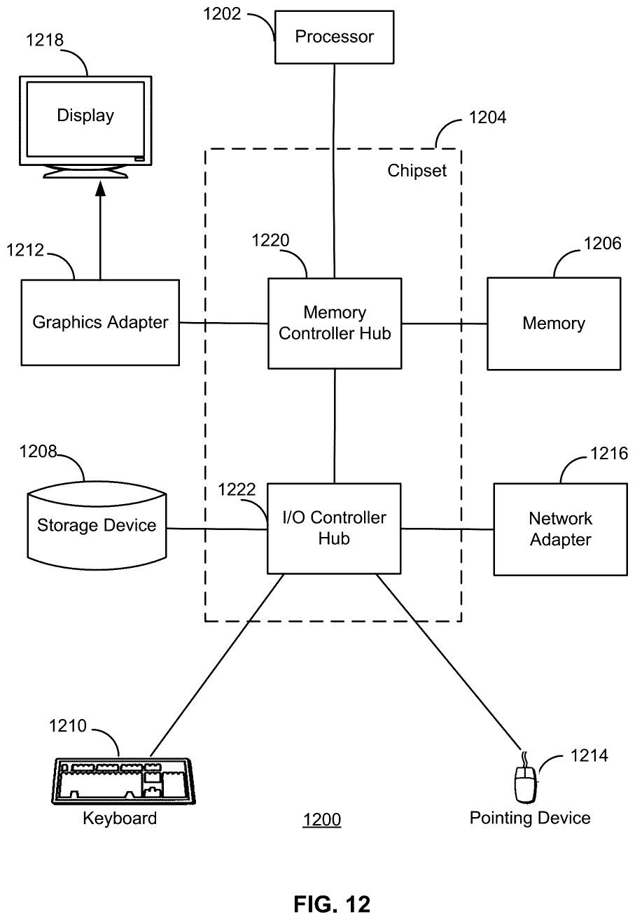

FIG. 12 is a block diagram of a computer 1200, in accordance with some embodiments. The computer 1200 is an example of circuitry that implements an adaptive control system, such as the adaptive control system 150. Illustrated are at least one processor 1202 coupled to a chipset 1204. The chipset 1204 includes a memory controller hub 1220 and an input/output (I/O) controller hub 1222. A memory 1206 and a graphics adapter 1212 are coupled to the memory controller hub 1220, and a display device 1218 is coupled to the graphics adapter 1212. A storage device 1208, keyboard 1210, pointing device 1214, and network adapter 1216 are coupled to the I/O controller hub 1222. The computer 1200 may include various types of input or output devices. Other embodiments of the computer 1200 have different architectures. For example, the memory 1206 is directly coupled to the processor 1202 in some embodiments.

The storage device 1208 includes one or more non-transitory computer-readable storage media such as a hard drive, compact disk read-only memory (CD-ROM), DVD, or a solid-state memory device. The memory 1206 holds program code (comprised of one or more instructions) and data used by the processor 1202. The program code may correspond to the processing aspects described with reference to FIGS. 1 through 11.

The pointing device 1214 is used in combination with the keyboard 1210 to input data into the computer 1200. The graphics adapter 1212 displays images and other information on the display device 1218. In some embodiments, the display device 1218 includes a touch screen capability for receiving user input and selections. The network adapter 1216 couples the computer 1200 to a network. Some embodiments of the computer 1200 have different and/or other components than those shown in FIG. 12.

In some embodiments, the circuitry that implements an adaptive control system, such as the adaptive control system 150, may include an application-specific integrated circuit (ASIC), a field-programmable gate array (FPGA), or other types of computing circuitry.

### Additional Considerations

Example benefits and advantages of the disclosed configurations include adaptive audio adjustment due to the adaptive control system adapting to a device, associated audio rendering system, or user's environment (e.g., their surrounding noise, time of day, etc.). The adaptive control system may either be integrated into a device or stored on a remote server to be accessible on-demand. In this way, a device need not devote storage or processing resources to maintenance of a control system that is specific to the device's audio rendering system. Additionally, because the adaptive control system can map and track controllable parameters on a parametric space having a size that is flexible to the number of controllable parameters, the adaptive control system can flexibly, automatically adjust controllable parameters for various systems (in addition to audio rendering systems)

Certain embodiments are described as including logic or a number of components, modules, or mechanisms. Modules may constitute either software modules (e.g., code embodied on a machine-readable medium or in a transmission signal) or hardware modules. A hardware module is tangible unit capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as a hardware module that operates to perform certain operations as described.

Similarly, the methods described may be at least partially processor-implemented. For example, at least some of the operations of a method may be performed by one or processors or processor-implemented hardware modules. The performance of certain of the operations may be distributed among the one or more processors, not only residing within a single machine, but deployed across a number of machines. In some example embodiments, the processor or processors may be located in a single location (e.g., within a home environment, an office environment or as a server farm), while in other embodiments the processors may be distributed across a number of locations.

Unless specifically stated otherwise, discussions using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Some embodiments may be described using the expression “coupled” and “connected” along with their derivatives. It should be understood that these terms are not intended as synonyms for each other. For example, some embodiments may be described using the term “connected” to indicate that two or more elements are in direct physical or electrical contact with each other. In another example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the invention. This description should be read to include one or at least one and the singular also includes the plural unless it is obvious that it is meant otherwise.

Some portions of this description describe the embodiments in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all the steps, operations, or processes described.

Embodiments may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

What is claimed is:

1. A non-transitory computer readable storage medium storing executable instructions that, when executed by one or more processors, cause the one or more processors to:
receive a natural language instruction referencing at least an audio parameter of an audio rendering system and a description of the audio parameter;
determine a value of the audio parameter using a machine learning model trained to, based on the natural language instruction, determine the audio parameter; and
transmit an instruction to the audio rendering system to update the value of the audio parameter according to the description of the audio parameter.

2. The non-transitory computer readable storage medium of claim 1, wherein the instructions that, when executed by one or more processors, further cause the one or more processors to:
generate a natural language prompt requesting feedback from a user regarding the updated value of the audio parameter, wherein the transmitted instruction further causes the audio rendering system to output the natural language prompt;
receive the feedback from the user; and
re-train the machine learning model based on the feedback.

3. The non-transitory computer readable storage medium of claim 1, wherein the natural language instruction references the audio parameter indirectly using one or more descriptive keywords.

4. The non-transitory computer readable storage medium of claim 1, wherein the natural language instruction is a user utterance.

5. The non-transitory computer readable storage medium of claim 1, wherein the audio parameter is one of spatial processing side gain, low-frequency processing compression ratio, low-frequency processing makeup gain, mid-frequency processing gain, high-frequency processing gain, or voice processing gain.

6. The non-transitory computer readable storage medium of claim 1, wherein the instructions that, when executed by one or more processors, further cause the one or more processors to:
receive, from the audio rendering system, device information comprising an application presently used by a user to consume audio on the audio rendering system; and
select, based on the application, the machine learning model from a plurality of machine learning models.

7. The non-transitory computer readable storage medium of claim 1, wherein the instructions that, when executed by one or more processors, further cause the one or more processors to:
track values of the audio parameter on a parametric space; and
update the value of the audio parameter on the parametric space according to the description of the audio parameter.

8. The non-transitory computer readable storage medium of claim 7, wherein the tracked values of the audio parameter comprise a change in the values of the audio parameter over instructions transmitted to the audio rendering system.

9. The non-transitory computer readable storage medium of claim 1, wherein the instructions that, when executed by one or more processors, further cause the one or more processors to:
determine, based on the natural language instruction, a predefined value of the audio parameter on a parametric space, wherein the predefined value corresponds to the updated value of the audio parameter.

10. The non-transitory computer readable storage medium of claim 1, wherein the instructions that, when executed by one or more processors, further cause the one or more processors to:
determine, based on the natural language instruction, one of a maximum value or a minimum value of the audio parameter on a parametric space, wherein the maximum value or the minimum value corresponds to the updated value of the audio parameter.

11. The non-transitory computer readable storage medium of claim 1, wherein the description of the audio parameter is associated with a degree of change to adjust the audio parameter.

12. The non-transitory computer readable storage medium of claim 11, wherein the degree of change is within a normalized range of values between −1 and 1, and wherein the normalized range corresponds to a range of decibel values.

13. The non-transitory computer readable storage medium of claim 11, wherein the machine learning model is further trained to, based on the natural language instruction and tracked values of the audio parameter on a parametric space, determine the degree of change.

14. The non-transitory computer readable storage medium of claim 13, wherein the instructions that, when executed by one or more processors, further cause the one or more processors to:
receive device information from the audio rendering system, wherein the machine learning model is further trained to determine the audio parameter and the degree of change based on the device information.

15. The non-transitory computer readable storage medium of claim 13, wherein the instructions that, when executed by one or more processors, further cause the one or more processors to:
receive parametric space boundaries limiting the value of audio parameters on the parametric space;
create a training set comprising natural language instructions labeled with one of an audio parameter or degree of change; and
train the machine learning model using the parametric space boundaries and the training set.

16. The non-transitory computer readable storage medium of claim 1, wherein the natural language instruction further references another audio parameter of the audio rendering system and another description of the other audio parameter, and wherein the machine learning model is further trained to determine the other audio parameter.

17. The non-transitory computer readable storage medium of claim 1, wherein the machine learning model is a first machine learning model, wherein the instructions that, when executed by one or more processors, further cause the one or more processors to:
determine one or more context parameters, a given context parameter characterizing a context in which a user consumes audio from the audio rendering system;
determine a recommended audio parameter and a recommended degree of change to adjust the recommended audio parameter using a second machine learning model trained to, based on the one or more context parameters, determine the recommended audio parameter and the recommended degree of change; and
generate a natural language prompt recommending that the user apply an audio adjustment to the audio rendering system based on the recommended audio parameter and the recommended degree of change.

18. A system comprising, comprising:
one or more processors; and
a non-transitory computer readable storage medium storing executable instructions that, when executed by the one or more processors, cause the one or more processors to:
receive a natural language instruction referencing at least an audio parameter of an audio rendering system and a description of the audio parameter;
determine a value of the audio parameter using a machine learning model trained to, based on the natural language instruction, determine the audio parameter; and
transmit an instruction to the audio rendering system to update the value of the audio parameter according to the description of the audio parameter.

19. The system of claim 18, wherein the instructions that, when executed by one or more processors, further cause the one or more processors to:
generate a natural language prompt requesting feedback from a user regarding the updated value of the audio parameter, wherein the transmitted instruction further causes the audio rendering system to output the natural language prompt;
receive the feedback from the user; and
re-train the machine learning model based on the feedback.

20. A method comprising:
receiving a natural language instruction referencing at least an audio parameter of an audio rendering system and a description of the audio parameter;
determining a value of the audio parameter using a machine learning model trained to, based on the natural language instruction, determine the audio parameter; and
transmitting an instruction to the audio rendering system to update the value of the audio parameter according to the description of the audio parameter.
